(19) United States
(12) Patent Application Publication
(10) Pub. No.: US 2025/0309878 A1
(43) Pub. Date: Oct. 2, 2025

(54) SEMICONDUCTOR DEVICE FOR MONITORING A CLOCK SIGNAL AND METHOD FOR ANALYZING CHARACTERISTICS OF A CLOCK SIGNAL

(71) Applicants: SK hynix Inc., Icheon-si (KR); SEOUL NATIONAL UNIVERSITY R&DB FOUNDATION, Seoul (KR)

(72) Inventor: Jaeha Kim, Seoul (KR)

(21) Appl. No.: 19/076,834

(22) Filed: Mar. 11, 2025

(30) Foreign Application Priority Data
Mar. 29, 2024 (KR) 10-2024-0042935

(51) Int. Cl. H03K 5/156; H03K 5/135

(52) U.S. Cl. CPC H03K 5/1565; H03K 5/135

(57) ABSTRACT

A semiconductor device includes a first macro circuit configured to generate a first monitoring signal by sampling a reference clock signal according to a first clock signal. A frequency of the reference clock signal and a frequency of the first clock signal have a predetermined frequency difference. A method for analyzing characteristics of a clock signal includes: accumulating a monitoring signal by sampling a reference clock signal according to a clock signal to generate a sample set, each of the sample sets having a size M times N, M being to the number of groups, N being the number of bins corresponding to the period of the reference clock signal, the reference clock signal and the clock signal having a predetermined frequency difference; and performing a first operation to estimate a jitter histogram of the clock signal by analyzing the sample set.

### CROSS-REFERENCE TO RELATED APPLICATION

The present application claims priority to Korean Patent Application No. 10-2024-0042935, filed on Mar. 29, 2024, which is incorporated herein by reference in its entirety.

### BACKGROUND

### 1. Technical Field

Embodiments relate to a semiconductor device for monitoring a clock signal and a method for analyzing characteristics of a clock signal.

### 2. Related Art

Clock signals used inside integrated circuits suffer from quality degradation such as jitter, phase noise, and duty cycle degradation due to various causes during generation and distribution process.

In order for integrated circuits to operate normally, it is desirable to keep the phase noise and jitter of the clock signal low, and to analyze the characteristics of the clock signal such as phase noise, jitter, and duty cycle of the clock signal.

### SUMMARY

In accordance with an embodiment of the present disclosure, a semiconductor device may include a first macro circuit configured to generate a first monitoring signal by sampling a reference clock signal according to a first clock signal, wherein a frequency of the reference clock signal and a frequency of the first clock signal have a predetermined frequency difference.

In accordance with an embodiment of the present disclosure, a method for analyzing characteristics of a clock signal may include accumulating a monitoring signal by sampling a reference clock signal according to a clock signal to generate a sample set, each of the sample sets having a size M times N, M being to the number of groups, N being the number of bins corresponding to a period of the reference clock signal, the reference clock signal and the clock signal having a predetermined frequency difference; and performing a first operation to estimate a jitter histogram of the clock signal by analyzing the sample set.

### BRIEF DESCRIPTION OF THE DRAWINGS

The accompanying figures, where like reference numerals refer to identical or functionally similar elements throughout the separate views, together with the detailed description below, are incorporated in and form part of the specification, and serve to further illustrate embodiments that include various features, and explain various principles and beneficial aspects of those embodiments.

FIG. 1 illustrates a semiconductor device according to an embodiment of the present disclosure.

FIG. 2 illustrates a monitoring circuit according to an embodiment of the present disclosure.

FIG. 3 illustrates effect of jitter included in a clock signal.

FIGS. 4, 5A, 5B, 5C, 6A, 6B, and 6C illustrate jitter histogram estimation operation of an analysis circuit according to an embodiment of the present disclosure.

FIGS. 7A and 7B illustrate performance of jitter histogram estimation of an analysis circuit according to an embodiment of the present disclosure.

FIGS. 8, 9, and 10 illustrate phase noise estimation operation of an analysis circuit according to an embodiment of the present disclosure.

FIGS. 11A, 11B, 12A, and 12B are graphs showing phase noise estimated by an analysis circuit according to an embodiment of the present disclosure.

FIGS. 13A and 13B are graphs showing performance of phase noise estimation of an analysis circuit according to an embodiment of the present disclosure.

FIGS. 14A and 14B are graphs showing relation between sensitivity and auto-correlation relation function.

FIG. 15 illustrates a monitoring circuit according to an embodiment of the present disclosure.

FIGS. 16A and 16B are graphs showing performance of duty cycle measurement of an analysis circuit according to an embodiment of the present disclosure.

FIG. 17 illustrates a monitoring circuit according to an embodiment of the present disclosure.

FIG. 18 illustrates a macro circuit according to an embodiment of the present disclosure.

### DETAILED DESCRIPTION

Various embodiments will be described below with reference to the accompanying figures. Embodiments are provided for illustrative purposes and other embodiments that are not explicitly illustrated or described are possible. Further, modifications can be made to embodiments of the present disclosure that will be described below in detail.

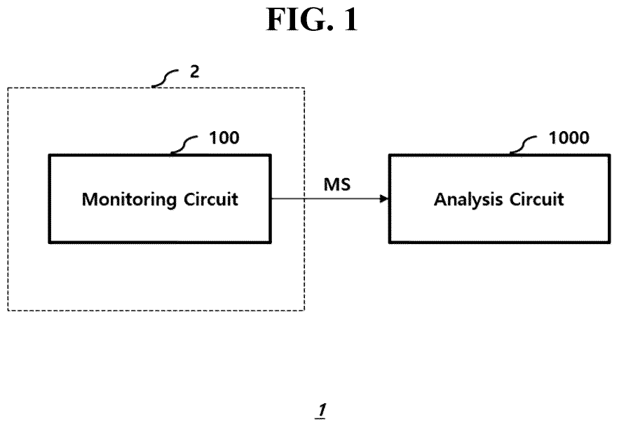

FIG. 1 is a block diagram showing a semiconductor device 1 according to an embodiment of the present disclosure.

The semiconductor device 1 includes a monitoring circuit 100 that monitors a clock signal to generate a monitoring signal MS.

The semiconductor device 1 may further include an analysis circuit 1000 that analyzes the characteristics of the clock signal using the monitoring signal MS.

The monitoring circuit 100 may be located inside an integrated circuit 2 that uses the clock signal.

The analysis circuit 1000 performs an analysis operation by accumulating the monitoring signal MS for a certain period of time and may be implemented by hardware, software, or a combination thereof. An operation of the analysis circuit 1000 will be specifically disclosed below.

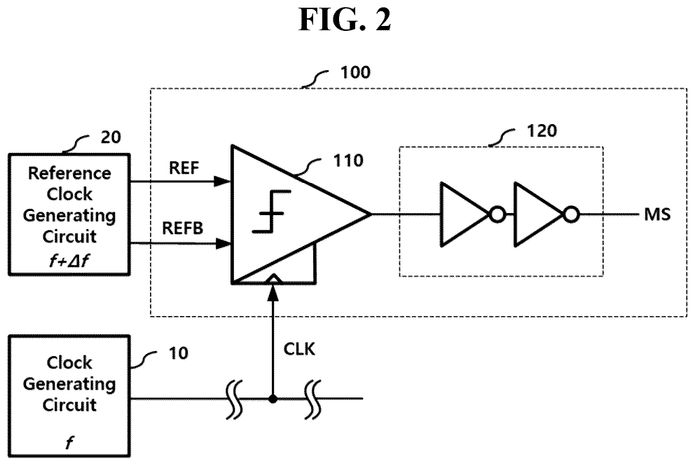

FIG. 2 is a block diagram showing a monitoring circuit 100 according to an embodiment of the present disclosure.

The monitoring circuit 100 monitors the clock signal CLK in the integrated circuit 2 and outputs the monitoring signal MS. The clock signal CLK may be provided through a clock distribution network within the integrated circuit 2, and the integrated circuit 2 may include a clock generating circuit 10 that generates the clock signal CLK.

The monitoring circuit 100 includes a sampling circuit 110.

The monitoring circuit 100 may further include a buffer circuit 120 that buffers an output of the sampling circuit 110.

The reference clock generating circuit 20 located outside the integrated circuit 2 generates a reference clock signal REF, and the reference clock signal REF is applied as an input of the sampling circuit 110.

However, embodiments of the present disclosure are not limited to this embodiment of FIG. 2, and in other embodiments, the reference clock generating circuit 20 may be included together with one or more elements within the integrated circuit 2.

The reference clock generating circuit 20 may further generate an inverted reference clock signal REFB that is opposite in phase to the reference clock signal REF.

The reference clock generating circuit 20 generates the reference clock signal REF having a frequency similar to a frequency of the clock signal CLK.

Hereinafter, the frequency of the clock signal CLK is represented as f, and the frequency of the reference clock signal REF is represented as f+Δf.

In this embodiment, the relationship between Δf and f can be determined in advance. For example, Δf has a value between about 0.5% and about 2.0% of f. In other words, the frequency difference Δf between the frequency f+Δf of the reference clock signal REF and the frequency f of the clock signal CLK is in a range from about 0.5% (e.g., 0.45% to 0.54%) to about 2.0% (e.g., 1.95 to 2.05%) of the frequency f of the clock signal CLK.

The sampling circuit 110 samples the reference clock signal REF according to the clock signal CLK.

More specifically, in this embodiment, the sampling circuit 110 samples difference between the reference clock signal REF and the inverted reference clock signal REFB, and the sampling circuit 110 outputs a high level signal corresponding to logic high ‘1’ when a value of the reference clock signal REF is greater than a value of the inverted reference clock signal REFB at the rising edge of the clock signal CLK, and outputs a low level signal corresponding to logic low ‘0’ otherwise.

As described above, the sampling circuit 110 samples the reference clock signal REF having a slightly different frequency from the clock signal CLK according to the clock signal CLK, and this sampling method may be referred to as incoherent sampling.

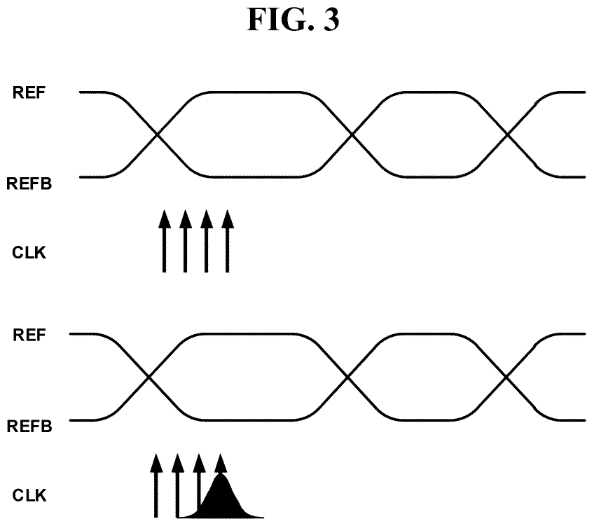

FIG. 3 is an explanatory diagram showing the effect of jitter of the clock signal according to an embodiment of the present disclosure.

If jitter exists in the clock signal CLK, the rising edge of the clock signal CLK may exist at a different position from where it should originally be over time.

In FIG. 3, jitter is shown only in the clock signal CLK, but jitter may exist in both the reference clock signal REF and the clock signal CLK. Accordingly, FIG. 3 can be understood as showing the relative jitter of the clock signal CLK.

Due to the frequency difference between the reference clock signal REF and the clock signal CLK, the edge of the clock signal CLK moves slightly based on the rising edge of the reference clock signal REF.

Accordingly, if there is no jitter, the sampling circuit 110 may periodically output a monotonous signal such as “ . . . 00001111 . . . ”

However, if jitter exists, the positions of 0 and 1 generated by the sampling circuit 110 may change in a complex manner over time to form a statistical distribution.

The analysis circuit 1000 accumulates the monitoring signal MS to estimate the statistical distribution related to the edge position of the clock signal CLK and analyzes the characteristics of the clock signal CLK therefrom.

Hereinafter, embodiments of a jitter histogram estimation method, a phase noise estimation method, a duty cycle estimation method, etc. will be described in relation to the operation method of the analysis circuit 1000 that analyzes the characteristics of the clock signal CLK using the monitoring signal MS.

### 1. Jitter Histogram Estimation

The analysis circuit 1000 according to an embodiment of the present disclosure can estimate a jitter histogram using the monitoring signal MS and analyze the characteristics of the clock signal CLK therefrom.

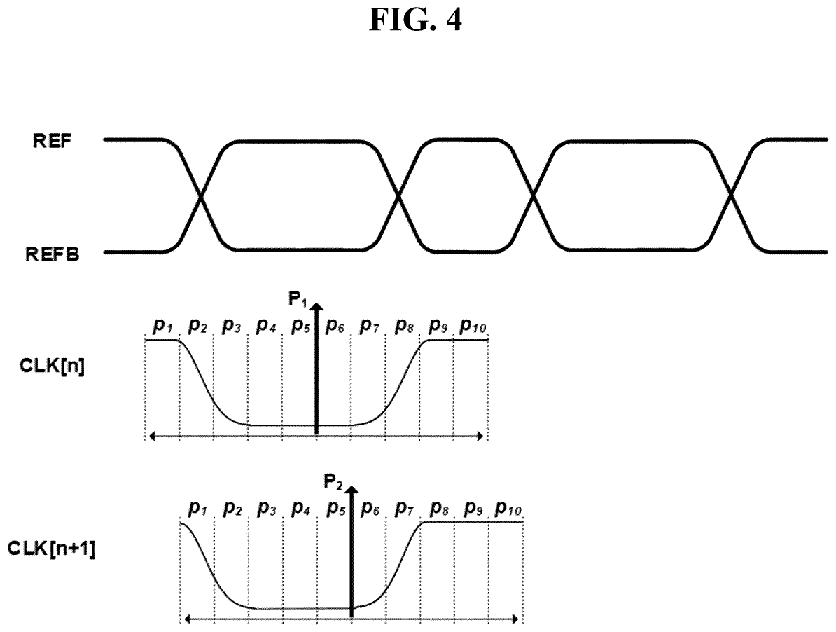

FIGS. 4 to 6C are graphs showing a jitter histogram estimation operation according to an embodiment of the present disclosure.

In such an embodiment, a period of the reference clock signal REF is divided into a plurality of bins. In this case, the rising edge of the clock signal CLK is located in one of the plurality of bins due to jitter.

Hereinafter, an embodiment in which a period of the reference clock signal REF is divided into 10 bins will be described, but the number of bins can be changed in various ways by a person skilled in the art according to embodiments of the present disclosure.

In FIG. 4, it is assumed that the rising edge of the clock signal CLK is located at the boundary between bin 5 and bin 6 when there is no jitter. The index indicating the bin around the rising edge of the clock signal CLK will be described again in detail below.

The clock signal CLK samples different points of the reference clock signal REF over time. FIG. 4 shows the rising edge of the clock signal CLK[n] at time t=n and the rising edge of the clock signal CLK[n+1] at time t=n+1, and shows the relative position change of the reference clock signal REF and the clock signal CLK according to the time.

First, Pₙ is defined as the probability that the reference clock signal REF sampled by the clock signal CLK at t=n becomes a first level (e.g., a high level).

During the incoherent sampling operation, the clock signal CLK samples the same position of the reference clock signal REF at regular intervals, and samples different positions of the reference clock signal REF at the same intervals every time within a single period.

For example, if the period of the reference clock signal REF is 9 ns and the period of the clock signal CLK is 10 ns, the clock signal CLK samples the same point of the reference clock signal REF every 90 ns.

In the monitoring signal MS observed for a certain period of time, the probability Pₙ that the value of the reference clock signal REF sampled by the clock signal CLK at t=n becomes 1 can be calculated, and a probability distribution histogram corresponding to the waveform of the reference clock signal REF can be generated by gathering probabilities corresponding to multiple points in time within a single period of the reference clock signal REF.

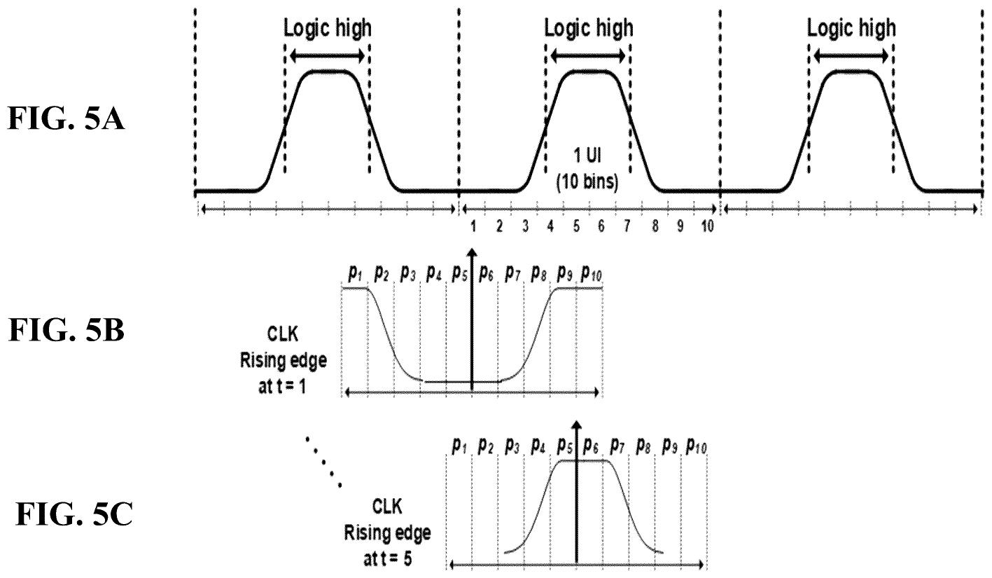

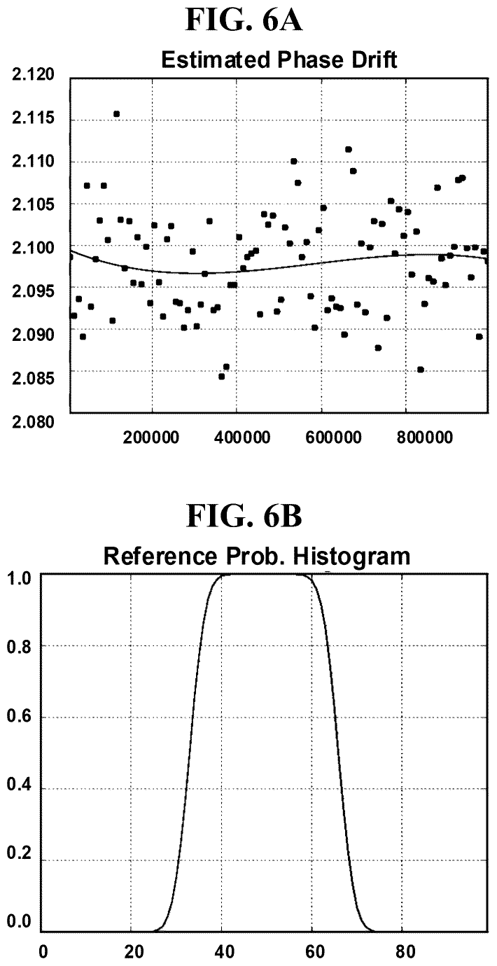

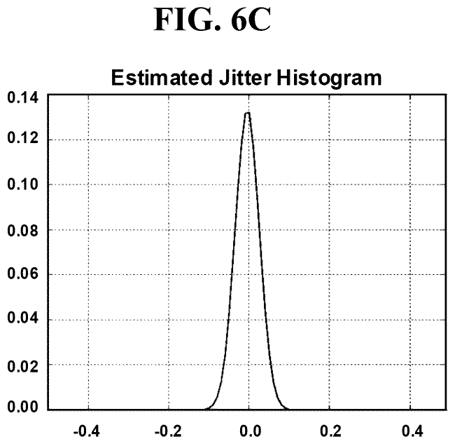

FIG. 5A shows the probability distribution histogram repeatedly in time order. FIG. 6B shows the probability distribution histogram generated when the number of bins is 100.

Next, pⱼ is defined as the probability that the j-th bin is included in the logic high level section of the reference clock signal REF, and p_{n,j} is defined as the probability that the j-th bin is included in the logic high level section of the reference clock signal REF when t is n, where j is a natural number from 1 to 10.

The index j indicating a bin is set based on a number of bins belonging to a group that includes the rising edge of the clock signal CLK.

At this time, the number of bins belonging to a group is the same as the number of bins set corresponding to a period of the reference clock signal REF, and FIGS. 4 and 5 illustrate a case where the number of bins belonging to a group is 10.

This embodiment of FIGS. 4 and 5 assumes that the rising edge of the clock signal CLK is located in the middle of a number of bins belonging to a group, and as shown in FIGS. 4 and 5, five bins are located on the left and right of the rising edge of the clock signal, and the index value j is sequentially assigned from 1 to 10 from the left.

In this embodiment, p_{n,j} can be calculated using the probability that a random value x exists within the range [x1, x2] in a specific distribution. At this time, the specific distribution is a normal distribution that approximates the probability distribution histogram generated earlier. Since the process of approximating the probability distribution histogram to a normal distribution is a known technique in the art, a detailed description is omitted for the interest of brevity.

At this time, p_{n,j} can be expressed as in Equation 1.

$${p}_{n , j} = {P}_{n} ( {x}_{1} \leq x \leq {x}_{2} ) = Q ( \frac{{x}_{1} - {μ}_{n}}{σ} ) - Q ( \frac{{x}_{2} - {μ}_{n}}{σ} ) \qquad [ Equation 1 ]$$

In Equation 1, Q is a Q function corresponding to an approximate normal distribution, un represents the average time point of the j-th bin at t=n, and σ is the standard deviation of the approximate normal distribution.

For example,, it is assumed that the distribution corresponding to the high level is between [3.2, 6.6] based on 10 bins in the probability distribution histogram shown in FIG. 5A.

Referring to FIG. 5B, when t=1, when calculating p₈, i.e., p_{1,8}, μ₁ corresponds to 3. Accordingly, p_{1,8} can be calculated as in Equation 2.

$${p}_{1 , 8} = {P}_{1} ( 3.2 \leq x \leq 6.6 ) = Q ( \frac{3.2 - 3}{σ} ) - Q ( \frac{6.6 - 3}{σ} ) \qquad [ Equation 2 ]$$

In this way, we can calculate all p_{n,j}, where n and j are natural numbers from 1 to 10.

The relationship between Pₙ and p_{n,j} can be expressed as a linear combination as in Equation 3.

$$[ \begin{matrix}{p}_{1 , 1} & … & {p}_{1 , 10} \\ ⋮ & ⋱ & ⋮ \\ {p}_{10 , 1} & … & {p}_{10 , 10}\end{matrix} ] \cdot [ \begin{matrix}{x}_{1} \\ ⋮ \\ {x}_{10}\end{matrix} ] = [ \begin{matrix}{P}_{1} \\ ⋮ \\ {P}_{10}\end{matrix} ] \qquad [ Equation 3 ]$$

The coefficients x₁ to x₁₀ of the linear equation in Equation 3 can be obtained by applying the non-negative least square (NNLS) algorithm. Since the NNLS algorithm and the method of calculating the linear equation therewith are known in the art, detailed descriptions thereof may be omitted for the interest of brevity.

The x₁ to x₁₀ obtained by applying the NNLS algorithm are the jitter histogram values corresponding to the multiple bins, respectively.

The Kernel Density Estimation (KDE) algorithm can be applied to these values to calculate the jitter histogram corresponding to the continuous section, i.e. the jitter probability distribution function.

Hereinafter, a jitter histogram estimation operation according to an embodiment of the present disclosure will be described in more detail.

The period of the supervisory signal MS, which is f/Δf, is measured through power spectral density (PSD) analysis, and the number of bins N corresponding to a single period of the reference clock signal REF is determined through this.

For example, if the frequency of the reference clock signal REF is 1.01 GHz and the frequency of the clock signal CLK is 1 GHZ, the clock signal CLK samples the same point of the reference clock signal REF every 100 periods of the clocks signal CLK and N is 100.

Thereafter, M×N samples are acquired. Here, M is a predetermined natural number. If 100 monitoring signals MS are referred to as a single group, M corresponds to the number of groups. For example, if 1 million samples are acquired, samples corresponding to 10,000 groups are acquired.

The probability analysis of the output samples is performed in units of sets N.

At this time, the long-term phase drift of the clock signal CLK and the reference clock signal REF can be compensated.

Long-term phase drift is a phenomenon in which the phase of the clock signal CLK shifts over time. If a long-term phase drift exists, there is a phase difference between two samples belonging to different groups of the monitoring signal MS but corresponding to the same point, making it difficult to accurately generate a probability distribution histogram.

Long-term phase shift compensation can be specifically performed as follows.

First, the entire sample is divided into groups, and a phase offset (or a group phase shift value) is calculated for each group.

The difference between the center point within a group and the center point of the logic high level section within a group is determined as the phase offset corresponding to the group.

For example, if a group contains 100 samples, the center point within a group is 50.

In this case, if the center point of the logic high level section in one group is 50, the phase offset of the group becomes 0, if the center point of the logic high level section is 49, the phase offset of the group becomes 1, and if the center point of the logic high level section is 51, the phase offset of the other group becomes −1.

If the entire sample contains 10,000 groups, 10,000 phase offsets are determined.

In FIG. 6A, the horizontal axis represents the data index, and the vertical axis represents the magnitude of the phase shift. A dot in FIG. 6A corresponds to a group phase shift value (or phase offset data for a corresponding group).

Afterwards, a sample phase shift value (or the phase shift value for each sample) is predicted by applying, for example, a spline fitting technique to the phase offset data for each group.

If the predicted phase shift value is a decimal, it can be approximated to an integer according to a predetermined rule.

This indicates that, for example, if there are 1 million samples including 10,000 groups, the phase shift value for each of 1 million samples is predicted by applying the fitting technique to the phase offset data for 10,000 groups.

In FIG. 6A, the line represents a graph of the long-term phase shift value predicted for the entire sample.

Afterwards, the phase shift value is applied to each sample to adjust the value of the entire sample.

For example, if the phase shift value of a sample is determined to be 0, the sample value is maintained as is, if the phase shift value of the sample is determined to be 1, the sample value is replaced with the sample value one step ahead, and if the phase shift value of the sample is −2, the sample value can be replaced with the sample value two steps behind.

In this way, the long-term phase shift is compensated for and the values of the entire sample are adjusted.

If the equipment generating the two signals is synchronized to a signal of the same reference frequency, the long-term phase shift compensation operation can be omitted. For example, if the clock generating circuit 10 and the reference clock generating circuit 20 are synchronized to a signal of the same reference frequency, this step can be omitted according to embodiments.

Next, a probability distribution histogram corresponding to the reference clock signal REF is generated.

As aforementioned, the probability distribution histogram is shown in FIG. 5A, and detailed description thereof will be disclosed as follows.

The probability Pᵢ that 1 is sampled at the i-th point in time within a single period of the reference clock signal REF is calculated, where i is an integer from 1 to N.

The probability Pᵢ that 1 is sampled at the i-th point in time

within the period can be calculated from M values within the (k×N+i)-th set of samples. Here, k is an integer from 0 to M−1.

For example, if there are 1 million samples including 10,000 groups each having 100 samples, N is 100 and M is 10,000. In this case, if the number of 1s among 10,000 samples corresponding to i=1 is 100, Pᵢ is determined as 0.01.

FIG. 6B is a graph showing the probability that the i-th sample will be 1 within a period, which corresponds to the probability distribution histogram that 1 will be sampled at each time point.

After that, an equation is established between the linear combination composed of Pᵢ calculated at each time point and pⱼ calculated around each time point, and the NNLS algorithm is applied to determine the linear combination coefficient.

Since this is the same as described above, repeated disclosure is omitted for the interest of brevity.

For example, if a group includes 100 samples, a total of 100 linear combination coefficients can be determined, and the jitter histogram of the clock signal CLK can be estimated by applying the KDE algorithm described above to these values. FIG. 6C shows the estimated jitter histogram.

At this time, in order for the established equation to have a unique solution, the matrix composed of linear combinations must be linearly independent. Since duplicate linear combinations may be generated depending on the sampling point when the duty cycle is 50%, a unique solution may exist when the duty cycle of the clock signal CLK is not 50%.

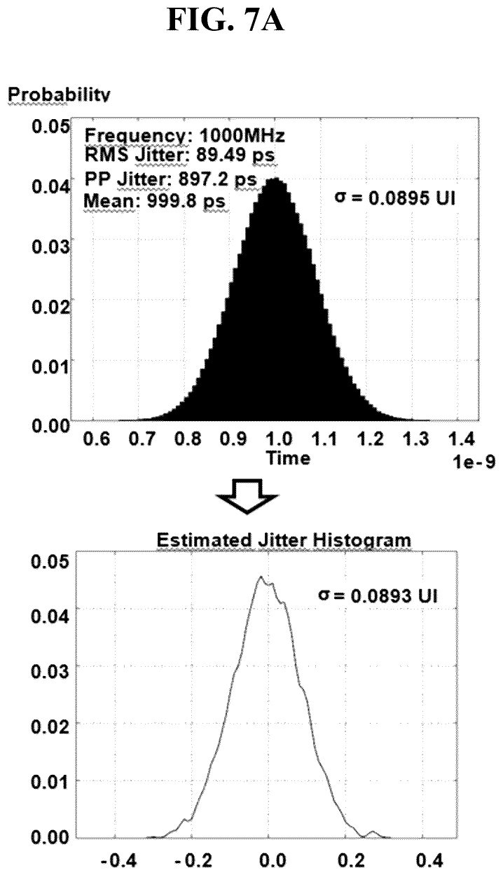

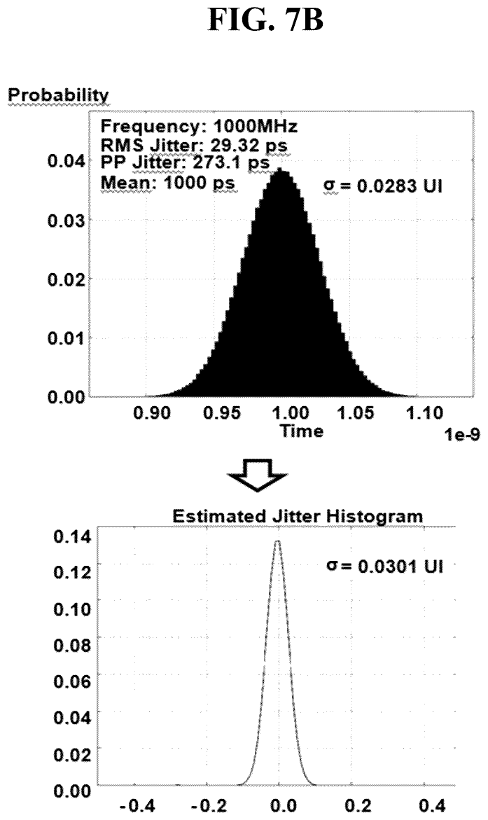

FIGS. 7A and 7B are graphs showing the jitter histogram estimation performance of the analysis circuit 1000 according to an embodiment of the present disclosure.

FIG. 7A shows a jitter histogram generated through simulation, and FIG. 7B shows a jitter histogram generated when the analysis circuit 1000 operates in the manner described above.

Comparing the peak value and standard deviation of the jitter histogram in the graph shows that the jitter histogram estimated by this technique can be generated with sufficient accuracy.

### 2. Phase Noise Estimation

Hereinafter, a method for estimating the phase noise of a clock signal CLK using the monitoring signal MS in the analysis circuit 1000 will be described in detail.

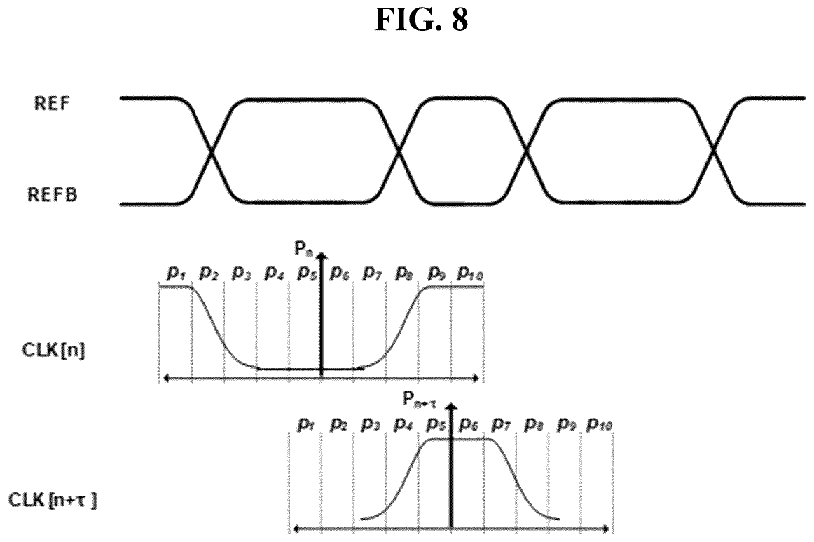

FIGS. 8 to 10 are diagrams showing a phase noise estimation operation according to an embodiment of the present disclosure.

As described above, a phase noise spectrum can be calculated using the monitoring signal MS accumulated to measure a jitter histogram.

In this embodiment, first, a correlation between the jitters of two clock signals with a certain time difference must be obtained, and the obtained correlation function is Fourier transformed to obtain a phase noise spectrum.

In this technology, as shown in FIG. 8, the probabilities that two samples obtained at a specific time point from two clock signals CLK[n], CLK[n+τ] with a certain time difference T are (0,0), (0,1), (1,0), (1,1) are calculated, and thus the joint probability distribution of the jitter corresponding to the two time points is calculated.

Two clock signals CLK[n] and CLK[n+τ] with a constant time difference T are both obtained from the same monitoring signal MS, and CLK[n+τ] has elements obtained by shifting elements of the CLK[n] by +τ through the analysis circuit 1000.

From this joint probability distribution, the auto-correlation function R(τ) and the phase noise spectrum S(f) can be calculated.

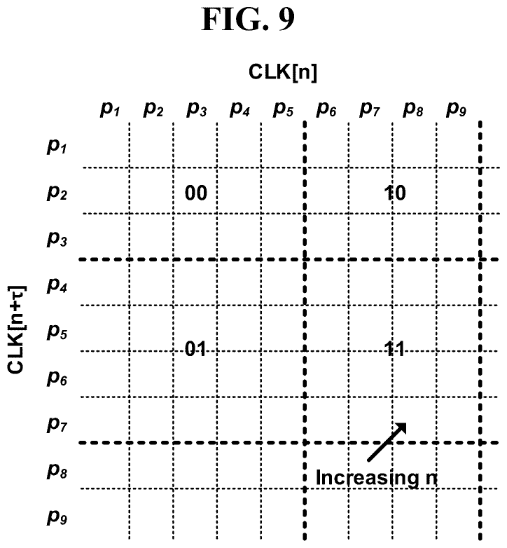

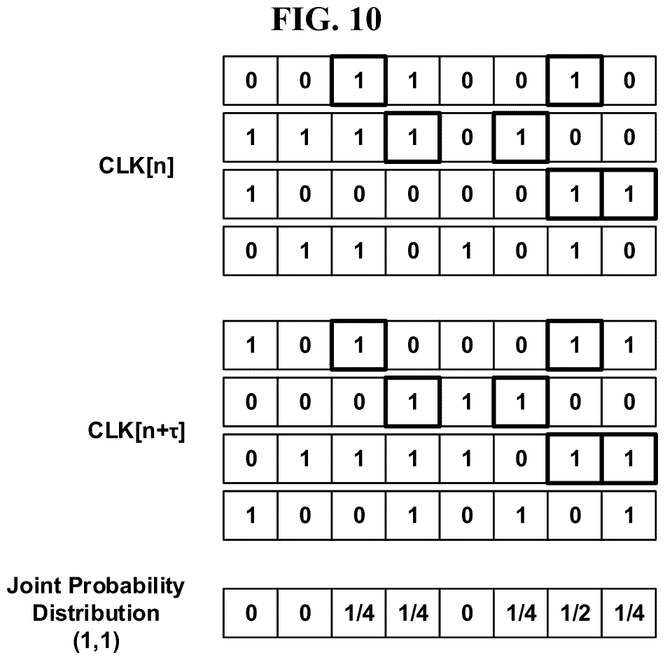

A method for calculating the joint probability distribution of jitter is disclosed in more detail with reference to FIGS. 9 and 10.

Assuming that the total number of samples includes 10,000 groups each having 100 samples as described above, there are 1 million samples for each of the two clock signals, and each can be organized into 10,000 groups each having 100 samples.

FIG. 10 briefly shows a method for determining a joint probability distribution corresponding to (1,1) in the case where a group includes 8 samples and a total of 4 groups exist.

1^{st}, 2^{nd} and 5^{th} bins do not have cases corresponding to (1,1), and thus the corresponding probability is 0. Each of 3^{rd}, 4^{th}, 6^{th}, and 8^{th} bins has 1 case corresponding to (1,1), so the corresponding probability is ¼. The 7^{th} bin has 2 cases corresponding to (1,1), so the corresponding probability is ½.

In this way, we can calculate the joint probability distribution corresponding to the two clock signals for each of the four combinations.

Next, the process of generating a two-dimensional jitter histogram from the joint probability distribution will be disclosed.

First, for a specific point in time, pᵢₓⱼ is defined as follows. Here, i×j is a natural number from 1 to N×N, and N corresponds to the number of bins, that is, the number of samples included in a single group.

pᵢₓⱼ is defined as the product of the first probability that the i-th bin is included in the logic high level section of the reference clock signal REF corresponding to CLK[n] and the second probability that the j-th bin is included in the logic high level section of the reference clock signal REF corresponding to CLK[n+τ]. Using this, a linear equation such as Equation 4 can be derived.

$$[ \begin{matrix}{p}_{1 , 1} & … & {p}_{1 , N \times N} \\ ⋮ & ⋱ & ⋮ \\ {p}_{4 N , 1} & … & {p}_{4 N , N \times N}\end{matrix} ] [ \begin{matrix}{x}_{1} \\ ⋮ \\ {x}_{N \times N}\end{matrix} ] = [ \begin{matrix}{P}_{1} \\ ⋮ \\ {P}_{4 N}\end{matrix} ] \qquad [ Equation 4 ]$$

In Equation 4, rows 1 to N correspond to the (1,1) combination, rows N+1 to 2N correspond to the (1,0) combination, rows 2N+1 to 3N correspond to the (0,1) combination, and rows 3N+1 to 4N correspond to the (0,0) combination.

The solutions of the above equation, x1, . . . , xN×N, represent jitter histogram values corresponding to N×N bins, which can be derived from the NNLS algorithm as described above.

At this time, the KDE algorithm can be additionally applied to the N×N jitter histogram values.

Since the above process generates a jitter histogram for a certain τ, a two-dimensional jitter histogram can be generated by changing τ.

From this, the autocorrelation function R (t, t+τ) can be calculated, and the phase noise spectrum S (f) can be obtained by applying the Fourier transform to the autocorrelation function R (t, t+τ).

The technique of deriving an autocorrelation function and a phase noise spectrum from a plurality of two-dimensional jitter histograms that vary with respect to T is known in the art, and thus a detailed description thereof is omitted for the interest of brevity.

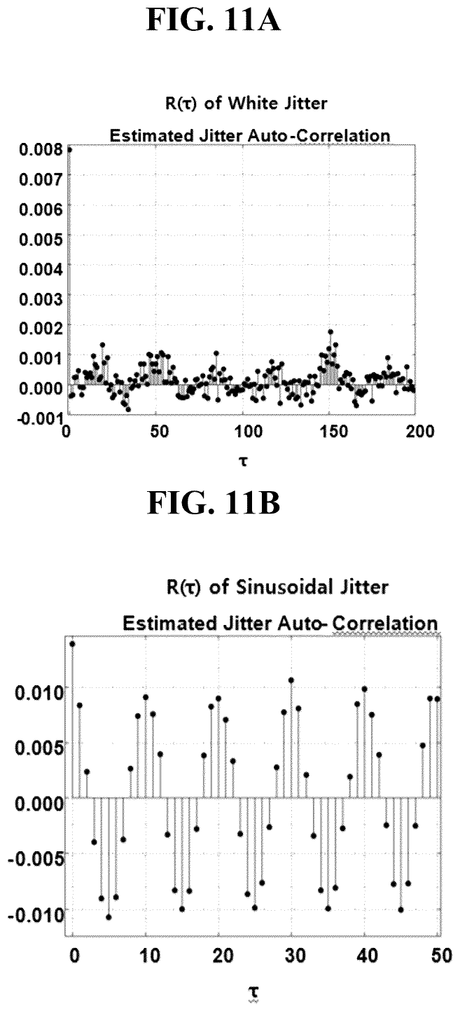

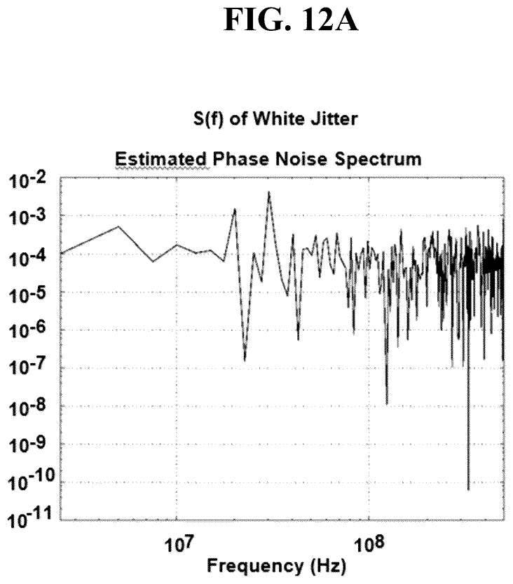

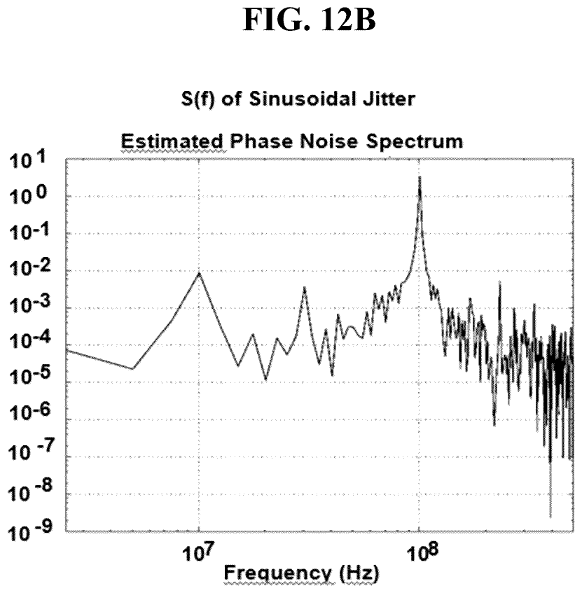

FIGS. 11A, 11B, 12A, and 12B are graphs showing an estimated correlation function and a phase noise spectrum from an analysis circuit 1000 according to an embodiment of the present disclosure.

FIGS. 11A and 11B show autocorrelation functions measured from a clock signal having white jitter and sinusoidal jitter using the above-described method, and FIGS. 12A and 12B show phase noise spectrums measured from a clock signal having white jitter and sinusoidal jitter using the above-described method.

In the embodiment of FIGS. 11A to 12B, 1 million samples of the monitoring signal MS are collected when the frequency of the clock signal CLK is 1 GHZ. FIGS. 11A to 12B show that the autocorrelation function and phase noise spectrum for each jitter have been obtained as expected.

That is, for white jitter, an impulse-type autocorrelation function that has a large value only when τ=0 and a phase noise spectrum with constant noise power over the entire frequency range are confirmed.

In addition, for sinusoidal jitter, a periodic sinusoidal autocorrelation function and a phase noise spectrum with power concentrated on the corresponding sinusoidal frequency are confirmed.

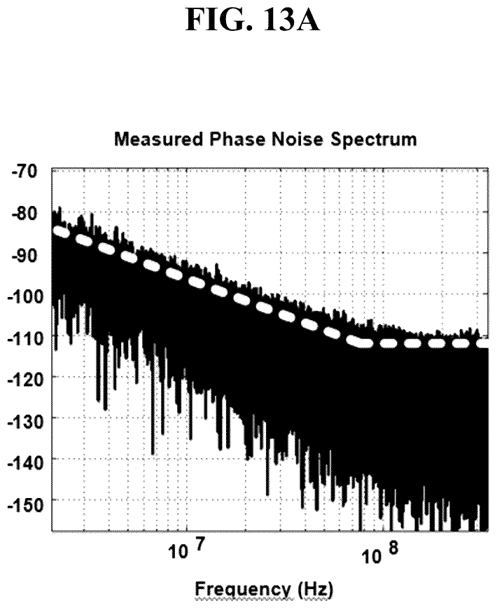

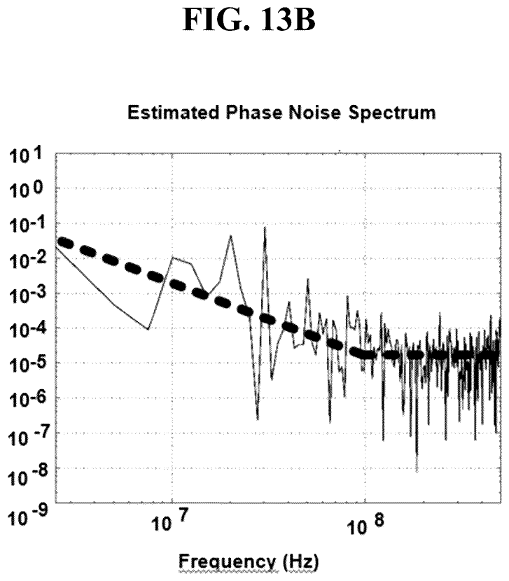

FIGS. 13A and 13B are graph showing the phase noise estimation performance of an analysis circuit 1000 according to an embodiment of the present disclosure.

FIG. 13A shows the result of measuring the phase noise spectrum for a clock signal having both white noise component and sinusoidal jitter, and FIG. 13B shows the phase noise spectrum estimated by applying the aforementioned method to the clock signal.

Since the measured autocorrelation function was calculated for a relatively narrow range of τ values from 0 to 200, the low-frequency phase noise is not well expressed, but it can be confirmed that it has the expected phase noise spectrum form.

Compared to the jitter histogram, phase noise spectrum measurement may be difficult.

For example, the autocorrelation function may be difficult to measure depending on the value of T due to the sensitivity of the measurement.

When the clock signal CLK samples the transition point of the reference clock signal REF, the sensitivity to the jitter of the clock signal CLK is high, and when the peak point of the reference clock signal REF is sampled, the sensitivity is 0 (i.e., the lowest value). Depending on the amount of jitter of the clock signal CLK and

the period value, the sensitivity of one of the two clock signals CLK[n] and CLK[n+τ] is low for a certain T value, making it difficult to measure the autocorrelation function.

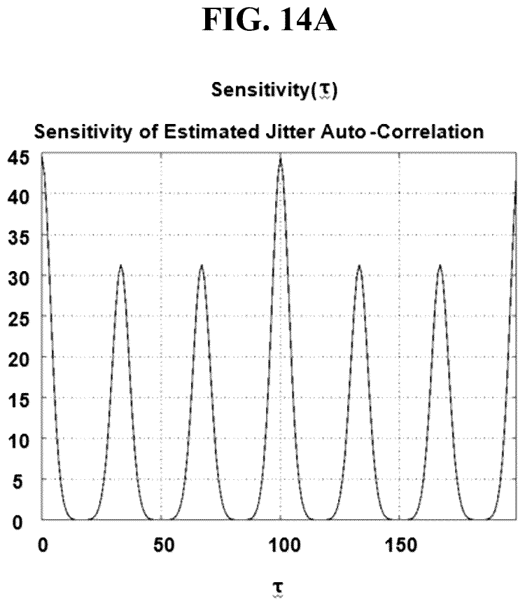

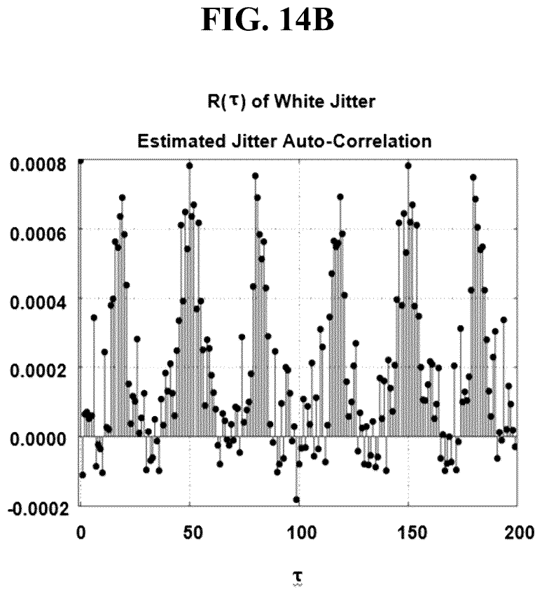

FIGS. 14A and 14B are graphs showing the relationship between sensitivity and autocorrelation function.

When the jitter level is low, as shown in FIG. 14A, there are many sections where the sensitivity drops to 0, and the value of the autocorrelation function measured in that section may become inaccurate.

To address these issues and improve the quality of phase noise measurements, the following two complementary operations can be additionally performed.

First, the inventors have found through experiments that the range of T having low sensitivity can be minimized when the duty cycle of the reference clock signal REF is made close to 33% or 67%. For example, the range of τ having low sensitivity can be unexpectedly minimized when the duty cycle of the reference clock signal REF is in a range from 30% to 36%, 32% to 34%, 32.5% to 33.5%, or 32.9% to 33.1%. Alternatively, the range of τ having low sensitivity can be unexpectedly minimized when the duty cycle of the reference clock signal REF is in a range from 64% to 70%, 66% to 68%, 66.5% to 67.5%, or 66.9% to 67.1%.

Next, the inventors have found that the overall phase noise measurement quality can be improved by performing multiple measurements with different N values i.e., different Δf and by selecting the autocorrelation function values with relatively high sensitivity.

### 3. Duty Cycle Estimation

Hereinafter, a method for estimating the duty cycle of a clock signal CLK using the monitoring signal MS in an analysis circuit 1000 will be disclosed.

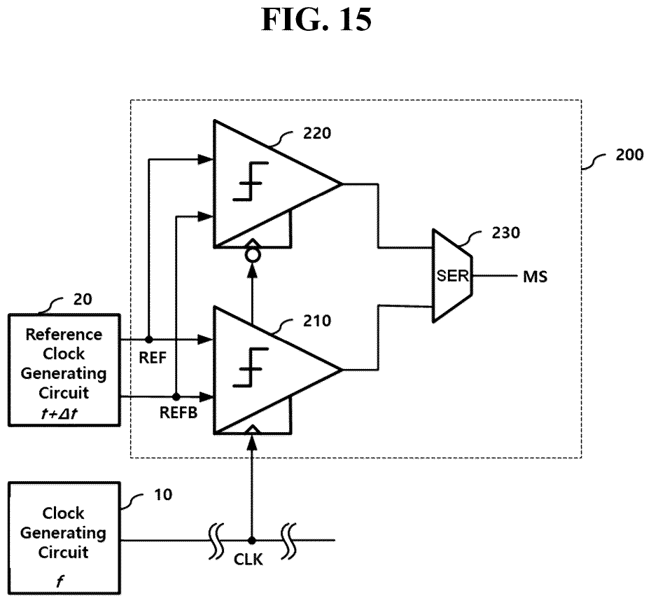

FIG. 15 is a block diagram showing a monitoring circuit 200 according to an embodiment of the present disclosure.

The monitoring circuit 200 includes a first sampling circuit 210, a second sampling circuit 220, and a serialization circuit 230.

The configuration and operation of the reference clock generating circuit 20 in FIG. 15 may be substantially the same as those of the reference clock generating circuit 20 in FIG. 2 as described above.

The first sampling circuit 210 samples the reference clock signal REF at a first edge (e.g., a rising edge) of the clock signal CLK, and the second sampling circuit 220 samples the reference clock signal REF at a second edge (e.g., a falling edge) of the clock signal CLK. The configuration and operation of each of the first sampling circuit 210 and the second sampling circuit 220 may be substantially the same as those of the sampling circuit 110 of the aforementioned FIG. 2.

In an embodiment, the serialization circuit 230 in FIG. 15 selects either an output of the first sampling circuit 210 or an output of the second sampling circuit 220 to provide an output thereof (e.g., the monitoring signal MS). Specifically, the serialization circuit 230 alternately outputs the output of the first sampling circuit 210 and the output of the second sampling circuit 220 to provide the monitoring signal MS.

In the embodiment of FIG. 15, the first sampling circuit 210 and the second sampling circuit 220 perform a sampling operation every cycle.

In another embodiment, in order to control the data rate, the first sampling circuit 210 and the second sampling circuit 220 may perform a sampling operation once every two cycles or other cycles of the clock signal CLK.

The analysis circuit 1000 separates odd samples and even samples, each corresponding to a sample by a rising edge and a falling edge.

For each separated data, a histogram of the probability that 1 is sampled at each point in time within the cycle can be obtained according to the method described above, each of which corresponds to the average waveform of the reference clock signal REF based on the rising edge and falling edge.

At this time, the time difference between the two waveforms can be measured, and the value becomes the duty cycle value to be measured.

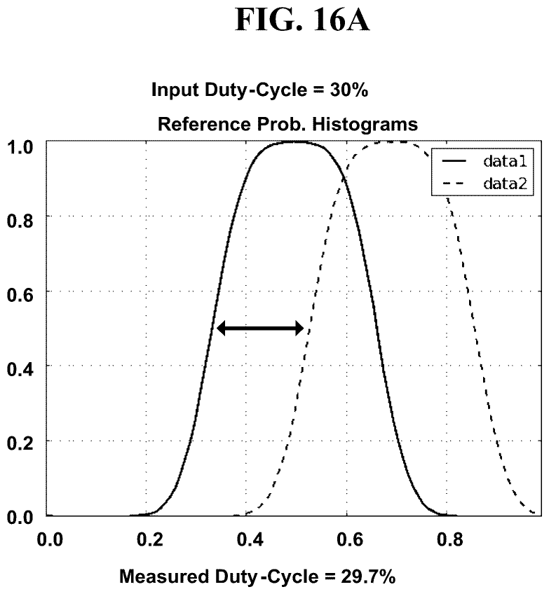

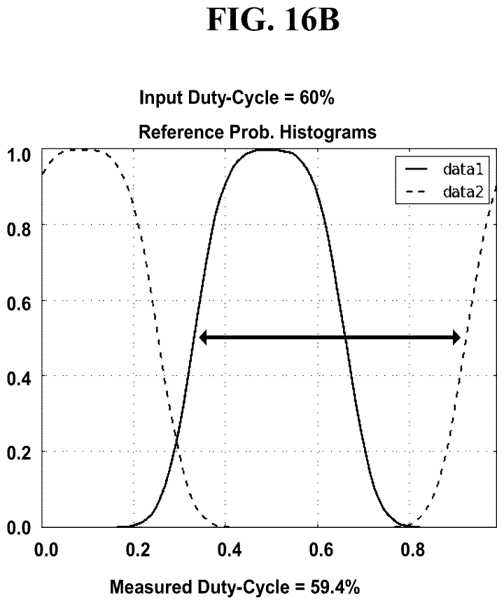

FIGS. 16A and 16B are graphs showing the duty cycle measurement performance of the analysis circuit 1000.

The graph shows that a duty cycle of about 29.7% was measured for a clock signal CLK having a duty cycle of 30%, and a duty cycle of about 59.4% was measured for a clock signal CLK having a duty cycle of 60%.

Through this, it can be confirmed that a relatively accurate level of duty cycle measurement is possible by embodiments of the present disclosure.

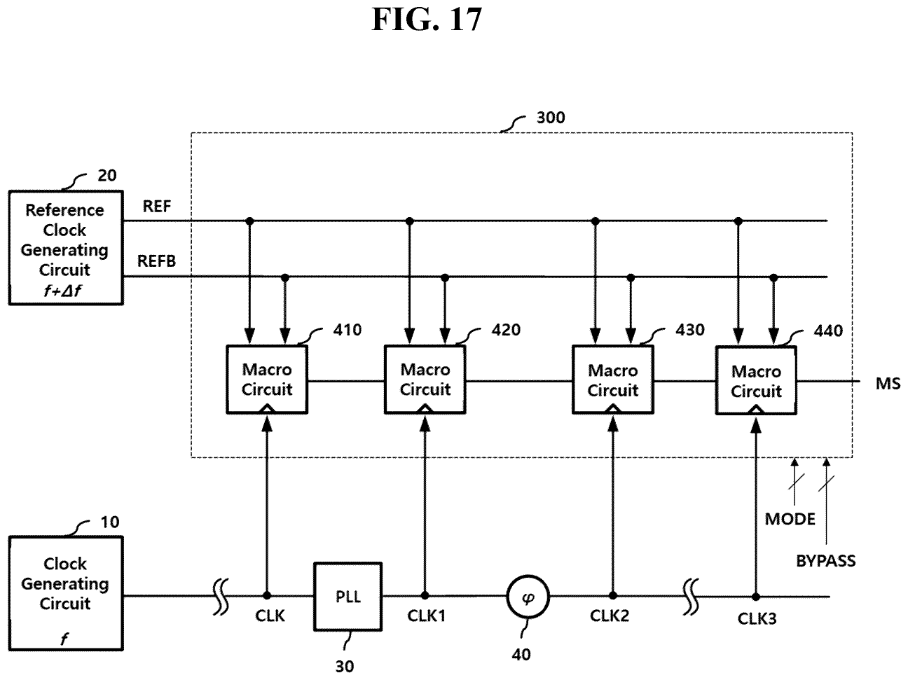

FIG. 17 is a block diagram showing a monitoring circuit 300 according to an embodiment of the present disclosure.

The monitoring circuit 100 of the aforementioned FIG. 2 generates a monitoring signal capable of measuring jitter and phase noise characteristics, and the monitoring circuit 200 of FIG. 15 generates a monitoring signal capable of measuring a duty cycle.

In this embodiment of FIG. 17, a monitoring circuit 300 that provides a monitoring signal capable of measuring jitter, phase noise, and duty cycle according to a mode is provided.

The configuration and operation of the reference clock generating circuit 20 are substantially the same as those of the reference clock generating circuit 20 in FIGS. 2 and 15 as described above.

The monitoring circuit 300 includes a plurality of macro circuits 410, 420, 430, and 440, and can measure characteristics such as jitter, phase noise, and duty cycle by using clock signals at necessary points in each macro circuit.

In some embodiments, the sampling circuit 110 and the buffer circuit 120 in the embodiment of FIG. 2 may correspond to the macro circuit of FIG. 17. In some embodiments, the first sampling circuit 210, the second sampling circuit 220, and the serialization circuit 230 in the embodiment of FIG. 15 may correspond to the macro circuit of FIG. 17.

A plurality of clock signals CLK, CLK1, CLK2, and CLK3 represent clock signals located at various points within an integrated circuit (e.g., the integrated circuit 2 in FIG. 1).

Their frequencies are all substantially the same as f and are based on clock signals generated by the clock generating circuit 10. The PLL circuit 30 and the phase modulator 40 are examples of circuits included in the integrated circuit 2 that transmit or convert clock signals.

A plurality of macro circuits 410, 420, 430, and 440 each may have the same structure.

Hereinafter, the macro circuit 410 may be referred to as the first macro circuit 410, the macro circuit 420 as the second macro circuit 420, the macro circuit 430 as the third macro circuit 430, and the macro circuit 440 as the fourth macro circuit 440.

In this embodiment, each macro circuit can selectively perform a bypass operation that receives a signal output from a neighboring macro circuit and transmits the received signal as is.

Through this, if there is a single pin that outputs a monitoring signal MS to the outside of the integrated circuit 2, and a single macro circuit among multiple macro circuits 410, 420, 430, and 440 operates at a time, the output of the macro circuit performing the operation can be selected and output as the monitoring signal MS.

The monitoring circuit 300 can control the operation mode and bypass operation of each of the multiple macro circuits using a multi-bit mode signal MODE and a bypass signal BYPASS.

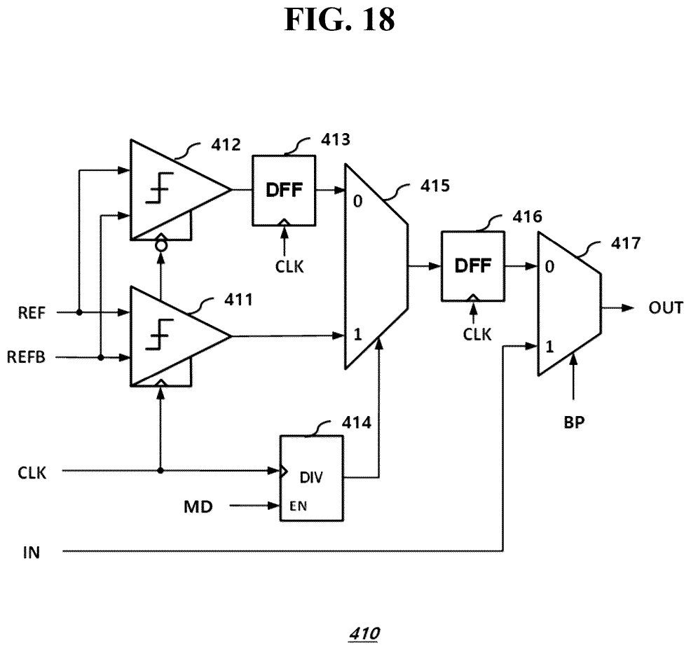

FIG. 18 is a block diagram showing a macro circuit 410 according to an embodiment of the present disclosure.

Hereinafter, the configuration and operation of the macro circuit will be described based on the first macro circuit 410. In this embodiment, it is assumed that the operation mode of the first macro circuit 410 is determined according to a mode signal MD and a bypass signal BP.

At this time, the mode signal MD corresponds to a corresponding bit among the multi-bit mode signal MODE of FIG. 17, and the bypass signal BP corresponds to a corresponding bit among the multi-bit bypass signal BYPASS of FIG. 17.

The first macro circuit 410 includes a first sampling circuit 411 that samples a reference clock signal REF at a first edge (e.g., a rising edge) of a clock signal CLK and a second sampling circuit 412 that samples a reference clock signal REF at a second edge (e.g., a falling edge) of the clock signal CLK.

The first macro circuit 410 includes a first flip-flop 413 that latches and outputs an output of the second sampling circuit 412 according to the clock signal CLK.

The first macro circuit 410 includes a clock divider (e.g., a frequency divider circuit) 414. The divider circuit 414 is activated according to the mode signal MD and outputs a signal that is divided by two times the cycle of the clock signal CLK. Specifically, when the mode signal MD has a second level (e.g., a high level), the divider circuit 414 generates an output signal with a frequency obtained by dividing a frequency of the clock signal CLK by a given value (e.g., 2). When the mode signal MD has a first level (e.g., the low level), the output of the divider circuit 414 is fixed to the high level.

The first macro circuit 410 includes a serialization circuit 415.

When the mode signal MD has the low level, the serialization circuit 415 fixedly selects the output of the first sampling circuit 411, and when the mode signal MD has the high level, the serialization circuit 415 performs a serialization operation according to the output of the divider circuit 414. That is, when the mode signal MD has the high level, the serialization circuit 415 may alternately output an output of the first sampling circuit 411 and an output of the second sampling circuit 412.

That is, when the mode signal MD has the low level, the macro circuit 410 can output a signal required for measuring jitter and phase noise, similar to the monitoring circuit 100 of FIG. 2, and when the mode signal MD has the high level, the macro circuit 410 can output a signal required for measuring duty cycle, similar to the monitoring circuit 200 of FIG. 15.

The first macro circuit 410 may include a second flip-flop 416 that latches and generate an output of the serialization circuit 415 according to the clock signal CLK.

The first macro circuit 410 may include a selection circuit 417 that selects either one of the output of the second flip-flop 417 and the input signal IN according to the bypass signal BP to generate an output signal OUT.

When the bypass signal BP is activated (e.g., the bypass signal BP having a high level), the first macro circuit 410 provides the input signal IN as the output signal OUT. At this time, the input signal IN may be the output of an adjacent macro circuit.

When the bypass signal BP is deactivated (e.g., the bypass signal BP having a low level), the first macro circuit 410 may output a signal required for measuring jitter and phase noise or a signal required for measuring duty cycle according to the mode signal MD.

Although some embodiments have been described above for illustrative purposes, various changes and modifications may be made to the above-described embodiments.

What is claimed is:

1. A semiconductor device comprising:
a first macro circuit configured to generate a first monitoring signal by sampling a reference clock signal according to a first clock signal,
wherein a frequency of the reference clock signal and a frequency of the first clock signal have a predetermined frequency difference.

2. The semiconductor device of claim 1, wherein the first macro circuit includes:
a first sampling circuit configured to sample the reference clock signal at a first edge of the first clock signal;
a second sampling circuit configured to sample the reference clock signal at a second edge of the first clock signal; and
a serialization circuit configured to select either an output of the first sampling circuit or an output of the second sampling circuit to provide an output thereof.

3. The semiconductor device of claim 2, further comprising:
a second macro circuit configured to generate a second monitoring signal by sampling the reference clock signal according to a second clock signal having substantially the same frequency as the first clock signal,
wherein the first macro circuit further includes a selection circuit configured to generate an output signal by selecting either an input signal or the output of the serialization circuit according to a bypass signal, the input signal being an output signal of a third macro circuit adjacent to the first macro circuit.

4. The semiconductor device of claim 2, wherein the serialization circuit outputs an output of the first sampling circuit when a mode signal has a first level, and alternately outputs the output of the first sampling circuit and an output of the second sampling circuit when the mode signal has a second level.

5. The semiconductor device of claim 4, wherein the first macro circuit further includes a clock divider dividing the clock signal when the mode signal has the second level.

6. The semiconductor device of claim 4, further comprising an analysis circuit configured to perform a first operation to estimate jitter histogram, a second operation to estimate phase noise spectrum, or a third operation to estimate a duty cycle of the first clock signal according to the first monitoring signal,
wherein the analysis circuit performs the first operation or the second operation when the mode signal has the first level and performs the third operation when the mode signal has the second level.

7. The semiconductor device of claim 6, wherein in order to perform the first operation, the analysis circuit:
accumulates the first monitoring signal to generate a sample set having a size M times N, M being the number of groups, N being the number of bins corresponding to a period of the reference clock signal,
determines a first probability that 1 is sampled at an i-th point in time within the period of the reference clock signal, i being an integer from 1 to N,
determines a plurality of second probabilities that a j-th bin among a plurality of bins is included in a logic high level section of the reference clock signal corresponding to the first probability, j being an integer from 1 to N, and
determines a jitter histogram from a linear combination relationship between the first probability and the plurality of second probabilities.

8. The semiconductor device of claim 7, wherein the first probability is calculated based on M values of (k×N+i)-th samples, k being an integer from 0 to M−1.

9. The semiconductor device of claim 7, wherein the analysis circuit determines M group phase shift values, each group including N samples from the sample set, determines a sample phase shift value corresponding to each sample included in the sample set from the M group phase shift values, and performs an operation of correcting each sample value of the sample set based on the sample phase shift value before determining the first probability.

10. The semiconductor device of claim 6, wherein in order to perform the second operation, the analysis circuit:
accumulates the first monitoring signal to generate a first sample set having a size M times N, M being to the number of groups, N being the number of bins corresponding to the period of the reference clock signal and a second sample set shifted by a predetermined time from the first sample set,
determines a first probability that a value of an i-th sample selected from the first sample set and a value of a j-th sample selected from the second sample set have a specific combination, i and j being an integer from 1 to N,
determines a plurality of second probabilities each corresponding to a product of a probability that an I-th bin corresponding to the first sample set is included in a logic high level section of the reference clock signal and a probability that an m-th bin corresponding to the second sample set is included in a logic high level section of the reference clock signal, l and m being an integer from 1 to N,
determines a two-dimensional jitter histogram from a linear combination relationship between the first probability and the plurality of second probabilities, and
determines a phase noise spectrum from the two-dimensional jitter histogram corresponding to the predetermined time.

11. The semiconductor device of claim 10, wherein a duty cycle of the reference clock signal is in a range from 30% to 36% or in a range from 64% to 70%.

12. The semiconductor device of claim 6, wherein the first edge is a rising edge and the second edge is a falling edge, and
wherein in order to perform the third operation, the analysis circuit:
accumulates the first monitoring signal to generate a first sample set corresponding to the rising edge of the first clock signal and a second sample set corresponding to the falling edge of the first clock signal, each of the first sample set and the second sample set having a size M times N, M being the number of groups, N being the number of bins corresponding to a period of the reference clock signal,
determines a first probability that 1 is sampled in the first sample set at an i-th point in time within the period of the reference clock signal and a second probability that 1 is sampled in the second sample set at a j-th point in time within the period of the reference clock signal, i and j being an integer from 1 to N, and
determines the duty cycle based on a first waveform determined from the first probability and a second waveform determined from the second probability.

13. The semiconductor device of claim 1, wherein the frequency difference between the reference clock signal and the first clock signal is in a range from about 0.5% to about 2.0% of the frequency of the first clock signal.

14. A method for analyzing characteristics of a clock signal, the method comprising:
accumulating a monitoring signal by sampling a reference clock signal according to a clock signal to generate a sample set, each of the sample sets having a size M times N, M being to the number of groups, N being the number of bins corresponding to a period of the reference clock signal, the reference clock signal and the clock signal having a predetermined frequency difference; and
performing a first operation to estimate a jitter histogram of the clock signal by analyzing the sample set.

15. The method of claim 14, wherein generating the sample set includes correcting phase shift for the sample set, and
wherein correcting the phase shift includes:
determining M group phase shift values, each group including N samples from the sample set;
determining a sample phase shift value corresponding to each sample included in the sample set from the M phase group shift values; and
correcting each sample value in the sample set based on the sample phase shift value.

16. The method of claim 14, wherein performing the first operation comprises:
determining a first probability that 1 is sampled at an i-th point in time within the period of the reference clock signal, i being an integer from 1 to N;
determining a plurality of second probabilities that a j-th bin among a plurality of bins is included in a logic high level section of the reference clock signal corresponding to the first probability, j being an integer from 1 to N, and
determines the jitter histogram from a linear combination relationship between the first probability and the plurality of second probabilities.

17. The semiconductor device of claim 16, wherein the first probability is calculated based on M values of (k×N+i)-th samples, k being an integer from 0 to M−1.

18. The method of claim 14, further comprising performing a second operation to estimate a phase noise spectrum of the clock signal,
wherein generating the sample set includes generating a first sample set including a size M times N and a second sample set shifted by a predetermined time from the first sample set, and
wherein performing the second operation includes:
determining a first probability that a value of an i-th sample selected from the first sample set and a value of a j-th sample selected from the second sample set have a specific combination, i and j being an integer from 1 to N;
determining a plurality of second probabilities each corresponding to a product of a probability that an I-th bin corresponding to the first sample set is included in a logic high level section of the reference clock signal and a probability that an m-th bin corresponding to the second sample set is included in a logic high level section of the reference clock signal, l and m being an integer from 1 to N;
determining a two-dimensional jitter histogram from a linear combination relationship between the first probability and the plurality of second probabilities; and
determining a phase noise spectrum from the relationship between the predetermined time and the two-dimensional jitter histogram.

19. The method of claim 18, wherein a duty cycle of the reference clock signal is in a range from 30% to 36% or in a range from 64% to 70%.

20. The method of claim 14, further comprising performing a third operation to estimate a duty cycle of the clock signal by analyzing the sample set,
wherein generating the sample set includes generating a first sample set corresponding to a rising edge of the clock signal and having a size M times N, and a second sample set corresponding to a falling edge of the clock signal and having a size M times N, and
wherein performing the third operation includes:
determining a first probability that 1 is sampled in the first sample set at an i-th point in time within the period of the reference clock signal, i being an integer from 1 to N;
determining a second probability that, 1 is sampled in the second sample set at a j-th point in time within the period of the reference clock signal, j being an integer from 1 to N; and
determining the duty cycle based on a first waveform determined from the first probability and a second waveform determined from the second probability.
